(19) United States
(12) Patent Application Publication
(10) Pub. No.: US 2026/0123286 A1
(43) Pub. Date: Apr. 30, 2026

(54) METHOD FOR MANUFACTURING DIELECTRIC ELASTOMER ACTUATOR, DIELECTRIC ELASTOMER ACTUATOR, APPARATUS, AND INFORMATION PROCESSING SYSTEM

(71) Applicant: SONY GROUP CORPORATION, TOKYO (JP)

(72) Inventors: Daisuke Yamamoto, TOKYO (JP); Yusaku Kato, TOKYO (JP); Ryo Iwamuro, TOKYO (JP); Takahito Suzuki, TOKYO (JP); Yoshio Goto, TOKYO (JP)

(21) Appl. No.: 19/115,477

(22) PCT Filed: Sep. 25, 2023
(86) PCT No.: PCT/JP2023/034680

§ 371 Date: Mar. 26, 2025

(30) Foreign Application Priority Data
Oct. 3, 2022 (JP) 2022-159670

(51) Int. Cl. H10N 30/20; H10N 30/085; H10N 30/098

(52) U.S. Cl. CPC H10N 30/20; H10N 30/085; H10N 30/098

(57) ABSTRACT

It is an object of the present disclosure to provide a new method for manufacturing a small rDEA. Further, it is also an object of the present disclosure to provide a small rDEA.

The present disclosure provides a method for manufacturing a rolled dielectric elastomer actuator, the method including a rolling step to roll at least one pair of complimentary electrode layers and a dielectric elastomer layer around a core to obtain a rolled body, a change step to change a state of the core after the rolling step, and a removal step to remove the core from the rolled body after the change step. Further, the present disclosure also provides a dielectric elastomer actuator that includes a rolled body of a laminate including at least one pair of complimentary electrode layers and a dielectric elastomer layer, the laminate having a thickness of 200 μm or less.

### TECHNICAL FIELD

The present disclosure relates to a method for manufacturing a dielectric elastomer actuator and the dielectric elastomer actuator. Further, the present disclosure relates to an apparatus that includes the actuator, and an information processing system.

### BACKGROUND ART

Various suggestions regarding dielectric elastomer actuators have been made in the past, and, for example, stack dielectric elastomer actuators, rolled dielectric elastomer actuators, and fiber dielectric elastomer actuators have been suggested. Those use the characteristics in that elastomer shrinks in a direction vertical to an electrode surface (extends in an in-plane direction).

Patent Literature 1 indicated below discloses, as an example of such dielectric elastomer actuators, an actuator that includes a dielectric elastomer and a plurality of voltage-applied members arranged through the dielectric elastomer, where the actuator operates by voltage being applied between the plurality of voltage-applied members, the voltage-applied member is formed into a fabric using stretchable thread including coiled thread made of carbon fiber, and the voltage-applied member is stretchable in response to the dielectric elastomer being deformed due to the application of the voltage (claim 1).

### CITATION LIST

### Patent Literature

Patent Literature 1: Japanese Patent Application Laid-open No. 2008-113544

### DISCLOSURE OF INVENTION

### Technical Problem

It may be desirable that dielectric elastomer actuators (hereinafter also referred to as “DEAs”) be made smaller in size so that the actuators can be used in various apparatuses.

With respect to the rolled dielectric elastomer actuators (hereinafter also referred to as “rDEAs”) from among the three types of DEAs described above, there are specific issues caused due to a structure thereof. For example, an rDEA has a structure in which a laminate including an electrode layer and an elastomer layer is rolled. Thus, it is very difficult to make the rDEA smaller in size. Further, the rolling can be performed accurately to some extent if the rolling is performed manually. However, it is very difficult to mass-produce the rDEA or automate the production of the rDEA. When, for example, the laminate rolled to manufacture an rDEA is made thinner in order to make the rDEA smaller in size, this results in causing a defect such as wrinkles often upon rolling. Such a defect is not allowed to be caused in, for example, an apparatus desired to be controlled precisely.

Thus, it is an object of the present disclosure to provide a new method for manufacturing a small rDEA. Further, it is also an object of the present disclosure to provide a small rDEA.

### Solution to Problem

The inventors have found out that a specific manufacturing method is useful in manufacturing an rDEA. Further, the inventors have also found out that the manufacturing method makes it possible to manufacture an rDEA that has not existed in the past.

In other words, the present disclosure provides a method for manufacturing a rolled dielectric elastomer actuator, the manufacturing method including a rolling step to roll at least one pair of complimentary electrode layers and a dielectric elastomer layer around a core to obtain a rolled body; a change step to change a state of the core after the rolling step; and a removal step to remove the core from the rolled body after the change step.

The core may be a core in a substantially columnar form.

The core may be a core that is in a substantially columnar form and formed using a material that liquid penetrates successfully.

The core may be a core that is in a substantially columnar form and that includes a fiber material or a porous material.

The core may be a hollow core in a substantially columnar form.

The manufacturing method may further include a cutting step to cut the rolled body obtained by the rolling around the core, such that a complimentary electrode layer of the at least one pair of complimentary electrode layers is exposed.

The rolled body obtained by the rolling step may include an adhesive layer between the core and the rolled body.

The adhesive layer may contain water-soluble polymers.

The change step may include bringing the core into contact with liquid or heating the core.

The change step may include bringing the core into contact with liquid, and the liquid may penetrate the core.

Further, the present disclosure also provides a dielectric elastomer actuator that includes a rolled body of a laminate including at least one pair of complimentary electrode layers and a dielectric elastomer layer, the laminate having a thickness of 200 μm or less.

The laminate may have a thickness of 100 μm or less.

The rolled body may include a hollow portion, and the hollow portion may have an inner diameter of 10 mm or less.

Furthermore, the present disclosure also provides an apparatus that includes the dielectric elastomer actuator.

The apparatus may be an operation input apparatus or a transducer.

Further, the present disclosure also provides an information processing system that includes the apparatus.

### BRIEF DESCRIPTION OF DRAWINGS

FIG. 1 is a diagram used to describe a principle of deformation of a DEA.

FIG. 2 is a schematic diagram used to describe a basic structure of an rDEA.

FIG. 3 is a flowchart of an example of a method for manufacturing an rDEA.

FIG. 4 is a flowchart of an example of a laminate forming step.

FIG. 5 is a schematic diagram used to describe the laminate forming step.

FIG. 6 is a flowchart of an example of a rolled body forming step.

FIG. 7 is a schematic diagram used to describe a rolling step.

FIG. 8 is a schematic diagram used to describe a change step.

FIG. 9 is a schematic diagram used to describe a cutting step without a core.

FIG. 10 is a schematic diagram used to describe the cutting step with a core.

FIG. 11 is a flowchart of an example of a modularization step.

FIG. 12 is a schematic diagram used to describe the modularization step.

FIG. 13 schematically illustrates an example of a mass production process.

FIG. 14 schematically illustrates the example of the mass production process.

FIG. 15 schematically illustrates the example of the mass production process.

FIG. 16 illustrates pictures of an rDEA.

FIG. 17 is a schematic diagram used to describe a difference in length between an outer-diameter-side portion of a rolled body and an inner-diameter-side portion of the rolled body.

FIG. 18 is a schematic diagram used to describe a size of a rolled body.

FIG. 19 schematically illustrates a cross section of an example of a lamination structure of a laminate.

FIG. 20 schematically illustrates an example of an operation input apparatus.

FIG. 21 schematically illustrates an example of an operation input apparatus.

FIG. 22A is a block diagram illustrating an example of a configuration of an information processing system.

FIG. 22B is a block diagram illustrating the example of the configuration of the information processing system.

FIG. 23 illustrates pictures used to describe stages of manufacturing processes.

FIG. 24 is a schematic diagram used to describe a size of a laminate.

FIG. 25 illustrates graphs used to describe a relationship among an inner diameter, outer diameter, and thickness of a rolled body.

FIG. 26 schematically illustrates a measurement system that measures a generated force.

FIG. 27A illustrates a result of measuring a generated force.

FIG. 27B is a graph in which a relationship between an applied voltage and a generated force is given.

FIG. 28 is a schematic diagram used to describe a removal step.

FIG. 29 is a schematic diagram used to describe an adhesive layer.

FIG. 30 is a schematic diagram used to describe exposure of an electrode layer.

### MODE(S) FOR CARRYING OUT THE INVENTION

Favorable embodiments for carrying out the present disclosure will now be described below. Note that embodiments described below are representative embodiments of the present disclosure, and the scope of the present disclosure is not limited to the embodiments described below.

The present disclosure is described in the following order.
1. First Embodiment (Manufacturing Method)
1.1 Driving Principle of DEA
1.2 Overview of Method for Manufacturing rDEA
1.3 Laminate Forming Step
1.4 Rolled Body Forming Step
1.5 Modularization Step
1.6 Example of Mass Production Process
2. Second Embodiment (rDEA)
3. Third Embodiment (Apparatus or System)
3.1 Example of Configuration of Apparatus (Button)
3.2 Example of Configuration of Apparatus (Plurality of rDEAs)
3.3 Example of Configuration of Apparatus (Transducer)
3.4 Example of Configuration of Apparatus (Endoscope Apparatus)
3.5 Example of Configuration of Information Processing System
4. Examples
4.1 Manufacturing of Rolled Body
4.2 Manufacturing of Rolled Bodies in Various Sizes
4.3 Manufacturing and Evaluation of rDEA

### 1. First Embodiment (Manufacturing Method)

### 1.1 Driving Principle of DEA

A DEA includes a dielectric elastomer and a pair of electrodes used to apply voltage to the dielectric elastomer. Electrodes of the pair of electrodes are pulled together by voltage being applied to the dielectric elastomer using the pair of electrodes. This results in deformation of the dielectric elastomer.

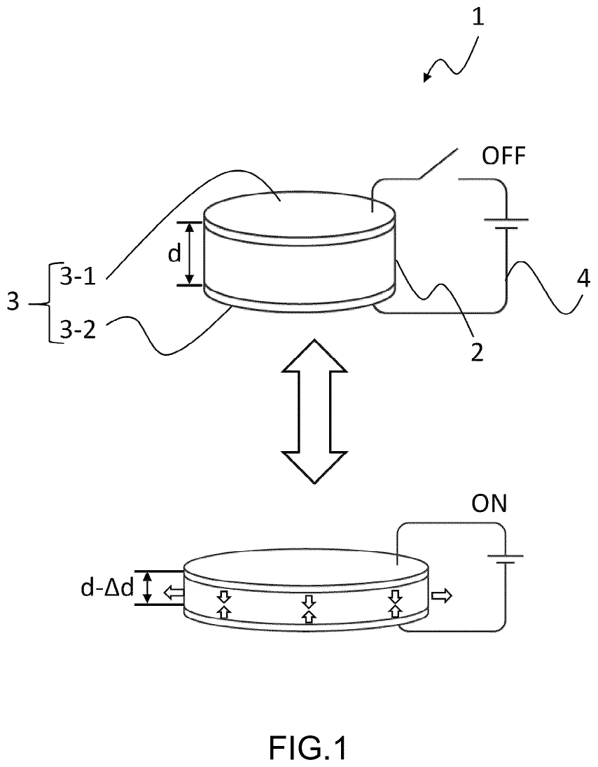

A principle of the deformation is described with reference to FIG. 1. The figure schematically illustrates a DEA. A DEA 1 includes a dielectric elastomer 2 and a pair of electrodes 3. The pair of electrodes 3 is arranged such that the dielectric elastomer 2 is situated between electrodes of the pair of electrodes 3, that is, an electrode 3-1 that is one of the pair of electrodes 3, the dielectric elastomer 2, and an electrode 3-2 that is another of the pair of electrodes 3 are stacked in this order. The pair of electrodes 3 is a portion of a circuit 4.

When voltage in the circuit 4 is off, the dielectric elastomer 2 has a thickness d in a direction that extends vertically to surfaces of the two electrodes, as illustrated in an upper portion of the figure.

When the voltage in the circuit 4 is turned on, voltage is applied between the two electrodes, as illustrated in a low portion of the figure. This results in the two electrodes being pulled together. As a result, the dielectric elastomer 2 shrinks in the direction extending vertically to the electrode surfaces, and extends in an in-plane direction. Accordingly, the thickness of the dielectric elastomer 2 in the direction extending vertically to the surfaces of the two electrodes is changed to d-Δd.

The DEA 1 can be used as a movable member due to the deformation described above.

Here, with respect to the shrinkage of the dielectric elastomer 2, a generated force and distortion in the shrinkage direction can be represented using respective formulas indicated below, where an applied voltage is V, a dielectric constant of the dielectric elastomer is ε, and a Young's modulus of the dielectric elastomer is Y.

$$Generated force P ∝ {ε ( \frac{V}{d} )}^{2} \qquad [ Math . 1 ]$$

$$Distortion S ∝ \frac{ε}{Y} {( \frac{V}{d} )}^{2}$$

As can be seen from these formulas, the adjustment of voltage applied to the DEA makes it possible to adjust an amount of deformation of and a generated force of the DEA.

A rolled DEA (rDEA) is an example of the DEA. The rDEA has, for example, a basic structure schematically illustrated in FIG. 2. An rDEA 5 illustrated in the figure includes a rolled body 6 of a laminate including at least one pair of complimentary electrode layers and a dielectric elastomer layer. The laminate may include a plurality of dielectric elastomer layers. Further, each of the plurality of dielectric elastomer layers may be situated between two electrode layers. The at least one pair of complimentary electrode layers may be electrically connected to a circuit 7. For example, the complimentary electrode layers (or electrodes electrically connected to the complimentary electrode layers) may be exposed from one of two bottom surface portions (bottom surface portions of a cylindrical form) of the rolled body or from the two bottom surface portions, and the exposed complimentary electrode layers may be connected to the circuit 7. Further, when voltage in the circuit 7 is turned on or off, the rolled body 6 extends or shrinks in a direction of a height of the cylindrical form, as illustrated in the figure. The extension or the shrinkage may be used as movability of the rDEA.

1.2 Overview of Method for Manufacturing rDEA

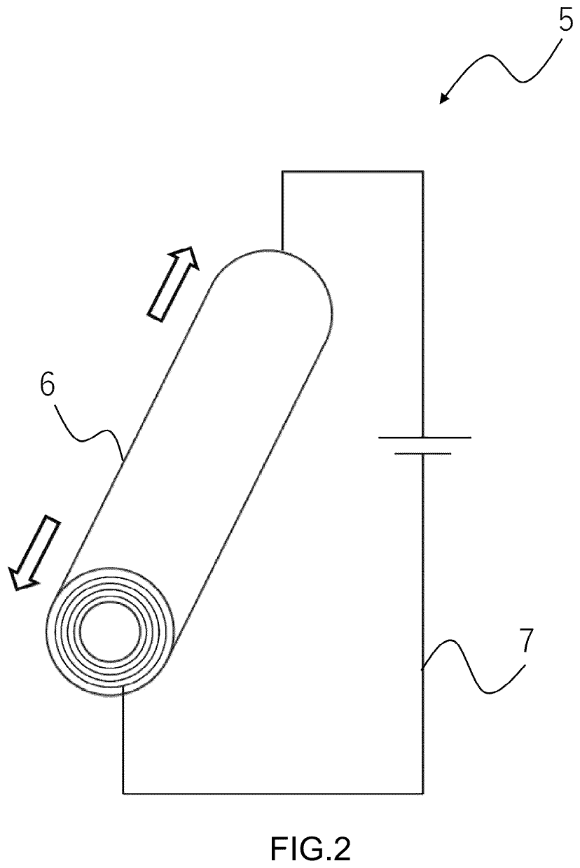

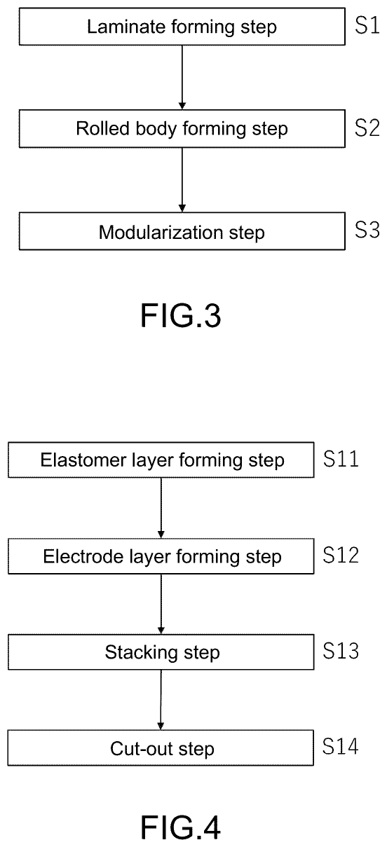

The method for manufacturing an rDEA is described with reference to FIG. 3. As indicated by the flowchart in the figure, the rDEA manufacturing method according to the present disclosure may include a laminate forming step S1 to obtain a laminate including an electrode layer and a dielectric elastomer layer, a rolled body forming step S2 to obtain a rolled body by rolling the laminate, and a modularization step S3 to form an rDEA by modularizing the rolled body.

The inventors have found out that the adoption of a specific approach in the rolled body forming step is very useful in manufacturing a small rDEA.

In the following description, the rolled body forming step is especially described in detail, and the laminate forming step and the modularization step are also described.

### 1.3 Laminate Forming Step

A laminate including at least one pair of complimentary electrode layers and a dielectric elastomer layer is formed in order to manufacture an rDEA.

The number of pairs of the complimentary electrode layers included in the laminate may be one, or at least two (such as two pairs, three pairs, or four pairs).

The number of the dielectric elastomer layers included in the laminate may be at least one, and favorably at least two. For example, the number may be two, three, or four. Each dielectric elastomer layer may be situated between complimentary electrode layers of a pair of complimentary electrode layers or between complimentary electrode layers of at least two pairs of complimentary electrode layers. In the latter case, at least two electrode layers may be patterned in one of surfaces of one dielectric elastomer layer such that the at least two electrode layers are not electrically connected to each other. The patterning enables an rDEA to not only extend and shrink in a single-axis direction but also to be bent in any direction.

A method for manufacturing the laminate may include, for example, an elastomer layer forming step S11, an electrode layer forming step S12, a stacking step S13, and a cut-out step S14, as indicated by, for example, a flowchart in FIG. 4. These steps are described below.

### (Elastomer Layer Forming Step S11)

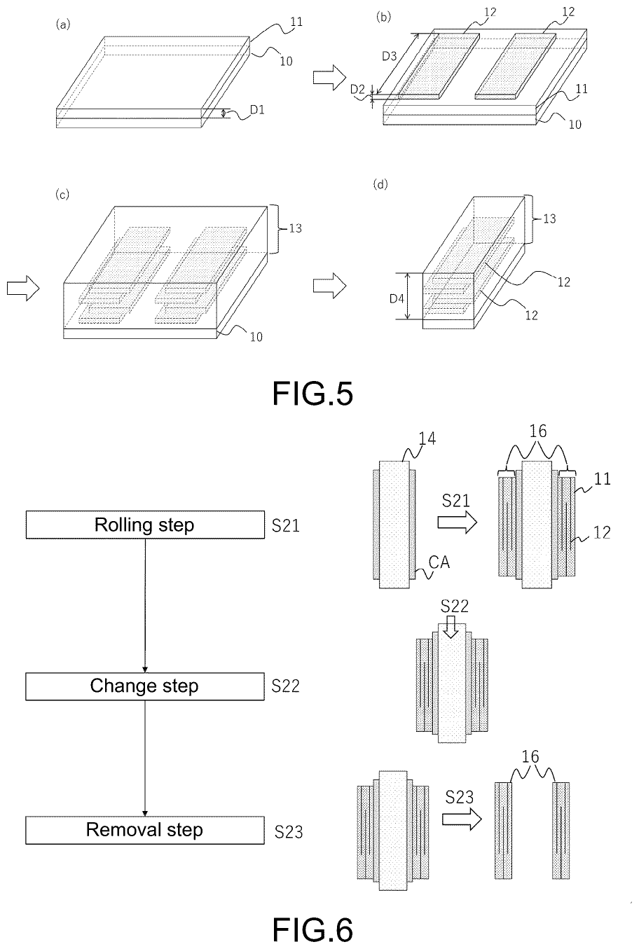

In the elastomer layer forming step S11, a dielectric elastomer layer 11 is formed on a base member layer 10, as illustrated in (a) of FIG. 5. The dielectric elastomer layer may be formed by coating the base member layer with an elastomer material and by curing the elastomer material, or may be formed by laminating, over the base member layer, a dielectric elastomer layer cured in advance.

For example, a thickness D1 of the dielectric elastomer layer 11 may be 100 μm or less, favorably 90 μm, 80 μm or less, 70 μm or less, or 60 μm or less, and more favorably 50 μm or less.

For example, the thickness D1 of the dielectric elastomer layer 11 may be 0.1 μm or greater, favorably 0.3 μm or greater, 0.5 μm or greater, or 0.7 μm or greater, and more favorably 1 μm or greater.

Each of an upper limit and a lower limit of a numerical-value range for the thickness D1 of the dielectric elastomer layer 11 may be selected from the numerical values listed above. For example, the thickness D1 may be 0.1 μm-100 μm, and favorably 1 μm-50 μm.

Voltage necessary for driving can be reduced by making a dielectric elastomer layer thinner. Further, a high insulting performance can be expected to be achieved by making a dielectric elastomer layer thicker. The numerical-value range having the upper and lower limits described above are suitable for reducing voltage necessary for driving and for preventing dielectric breakdown.

The dielectric elastomer layer 11 may be, for example, an insulating and elastic layer, and in particular, the dielectric elastomer layer 11 may be formed using an insulating elastomer. For example, the insulating elastomer may be a material obtained by curing an elastomer material that includes at least one of silicone resin, acrylic resin, or urethane resin as a principal component. In other words, the elastomer layer may be a silicone-based elastomer, an acrylic-based elastomer, or a urethane-based elastomer.

The elastomer material may include any additive. For example, the additive may include at least one of a crosslinker, a plasticizer, an antioxidant, a surfactant, a viscosity modifier, a reinforcement, or a colorant. A composition of the elastomer material may be selected as appropriate by those skilled in the art in this technical field. In other words, the dielectric elastomer layer may include at least one of these additives.

The base member layer 10 may be a base material that is formed using, for example, polyester-based resin, especially PET resin, or may be a base member that is formed using another material (such as polyolefin-based resin or polycarbonate-based resin). A material of the base member layer may also be selected as appropriate by those skilled in the art in this technical field.

Surface activation processing may be performed on the dielectric elastomer layer. For example, the surface activation processing is performed on a surface that is from between two surfaces of the elastomer layer and on which an electrode layer is stacked. For example, the surface activation processing may be plasma processing, corona discharge processing, or both of them. The surface activation processing results in improving interlayer adhesion, and thus in preventing unsticking of layers.

Further, the surface activation processing may be performed on another surface for which interlayer adhesion is desired to be improved.

For example, hydroxyl groups are given to a surface of a silicone-based elastomer by plasma processing being performed. This results in improving interlayer adhesion. For example, the surface activation processing may be performed before an electrode layer forming step S12. As a result, hydroxyl groups are given to a surface of a dielectric elastomer layer by the processing being performed. This leads to better wetting of an electrode layer forming material (such as an electrode paste), and then the improvement of printability can be expected. Further, the surface activation effect also contributes toward improving properties of adhesion of dielectric elastomer layers.

### (Electrode Layer Forming Step S12)

In the electrode layer forming step S12, the elastomer layer 11 is coated with an electrode layer 12, or the electrode layer 12 is printed onto the elastomer layer 11, as illustrated in (b) of FIG. 5. Favorably, the electrode layer 12 may be formed by screen printing. A conductive substance included in the electrode layer 12 may be, for example, carbon black, carbon nanotube (CNT), metallic filler, or a combination of at least two of them. For example, the electrode layer may be a layer formed by printing of a conductive ink including a conductive substance, and more specifically, the electrode layer may be a layer formed by screen printing of the conductive ink.

For example, a thickness D2 of the electrode layer 12 is 10 μm or less, and favorably 7 μm or less, 5 μm or less, or 3 μm or less. More favorably, the thickness D2 is 1 μm or less. In some embodiments, the thickness D2 of the electrode layer 12 may be, for example, 500 nm or less, 400 nm or less, 300 nm or greater, or 200 μm or less.

For example, the thickness D2 of the electrode layer 12 may be 10 nm or greater, and more favorably 20 nm or greater.

Each of an upper limit and a lower limit of a numerical-value range for the thickness D2 of the electrode layer 12 may be selected from the numerical values listed above. For example, the thickness D2 may be 10 nm-10 μm, and favorably 20 nm-1 μm.

When an electrode layer is thin, this contributes towards making a device lighter in weight and less rigid. On the other hand, when an electrode layer is too thin, this may result in a reduction in electrode coverage or an increase in an electric resistance of the electrode layer. A thickness of an electrode layer may be designed as appropriate by those skilled in the art according to, for example, the type of filler (having influence on electric resistance). For example, in the case of a CNT electrode, an electrode layer may have a thickness of about tens of nanometers, and an electrode layer including carbon-black-based filler may have a thickness of, for example, about tens of micrometers.

A length D3 in a rolling direction of the electrode layer 12 may be selected as appropriate by those skilled in the art according to a size of an rDEA to be manufactured, and does not necessarily have to be particularly limited. The length D3 may be, for example, 10 mm or greater, 20 mm or greater, 30 mm or greater, 40 mm or greater, or 50 mm or greater.

Further, an upper limit of the length D3 in the rolling direction of the electrode layer 12 also does not necessarily have to be particularly limited. The upper limit of the length D3 may be, for example, 500 mm or less, 400 mm or less, 300 mm or less, or 200 mm or less.

Each of an upper limit and a lower limit of a numerical-value range for the length D3 in the rolling direction of the electrode layer 12 may be selected from the numerical values listed above. For example, the length D3 may be 10 mm-500 mm, and favorably 20 mm-400 mm.

In an embodiment, the conductive ink may be conductive paste that includes carbon black and a binder component. In another embodiment, the conductive ink may be a conductive coating material that includes CNT. Such conductive ink is applied to the elastomer layer to form an electrode layer. In order to form the electrode layer, a curing step or a drying step may be performed as necessary after the application of the conductive ink.

### (Stacking Step S13)

In the stacking step S13, a second laminate obtained by stacking an electrode layer on a dielectric elastomer layer may be stacked on a first laminate obtained by stacking an electrode layer on a dielectric elastomer layer. In the stacking step S13, two laminates may be stacked on top of each other, and at least one different laminate obtained by stacking an electrode layer on a dielectric elastomer layer may be further stacked on the two laminates. In the stacking step S13, laminates each including an electrode layer and a dielectric elastomer layer may be stacked on top of each other, as described above. Accordingly, a laminate in which an electrode layer and a dielectric elastomer layer are stacked alternately, is formed.

Alternatively, an electrode layer may be formed on a dielectric elastomer layer, then an additional elastomer layer may be further stacked on the electrode layer, and then an additional electrode later may be further formed on the additional elastomer layer. Thereafter, an additional elastomer layer and an additional electrode layer may be further stacked thereon sequentially. In the stacking step S13, an electrode layer and an elastomer layer may be formed alternately, as described above.

As described above, in the stacking step S13, an electrode layer and an elastomer layer are stacked alternately, and a laminate 13 including at least one pair of complimentary electrode layers is obtained, as illustrated in (c) of FIG. 5.

For example, a thickness D4 of the laminate 13 (that is, a thickness of a laminate sheet to be rolled) may be 500 μm or less, 400 μm or less, or 300 μm or less, and favorably 200 μm or less. The thickness D4 may be more favorably 180 μm or less, and much more favorably 160 μm or less, 140 μm or less, 120 μm or less, or 100 μm or less.

It is desirable that the thickness D4 of the laminate 13 be thinner, and a lower limit of the thickness D4 does not necessarily have to be particularly set. For example, the thickness D4 may be 1 μm or greater, 5 μm or greater, 10 μm or greater, 15 μm or greater, 20 μm or greater, 25 μm or greater, or 30 μm or greater.

Each of an upper limit and a lower limit of a numerical-value range for the thickness D4 of the laminate 13 may be selected from the numerical values listed above. The thickness D4 may be, for example, 1 μm-500 μm, favorably, for example, 5 μm-200 μm, and more favorably 10 μm-180 μm.

The manufacturing method according to the present disclosure makes it possible to roll such a very thin laminate without causing a defect such as wrinkles, and also makes it possible to make an rDEA smaller in size.

### (Cut-Out Step S14)

In the cut-out step S14, cut-out is performed on the laminate obtained in the stacking step S13. The cut-out is performed such that an electrode layer is exposed from a surface formed by cut-out being performed. The electrode layer 12 is exposed from a surface created by the cut-out, as illustrated in (d) of FIG. 5. The electrode layer exposed as described above is electrically connected to a circuit upon modularization described later. Accordingly, functions of an rDEA are exerted.

### 1.4 Rolled Body Forming Step

In the rolled body forming step, a rolled body is formed using the laminate formed in the laminate forming step. The rolled body forming step includes a rolling step S21 to roll the laminate around a core to obtain a rolled body, a change step S22 to change a state of the core after the rolling step, and a removal step S23 to remove the core from the rolled body after the change step, as indicated by, for example, a flowchart in FIG. 6.

In the rolling step S21, the laminate is rolled around the core 14 to form a rolled body 16, as indicated by a schematic cross-sectional view (a cross-sectional view along a plane including an axis of the rolled body) on the right in the figure. The rolled body 16 may be a rolled body of a laminate including the dielectric elastomer layer 11 and the electrode layer 12. An adhesive layer CA may be provided to an outer periphery of the core 14, as described later, and the core 14 and the rolled body 16 may be bonded to each other through the adhesive layer CA, as illustrated in the figure. In the change step S22, there is a change in a state of the core 14. In the change step, there may also be a change in a state of the adhesive layer CA. Then, in the removal step S23, the core 14 is removed from the rolled body 16. In the removal step, the adhesive layer CA may also be removed. When a rolled body is manufactured as described above, a size of an rDEA (a rolled body in particular) can be controlled by an outer diameter of a core, as well as a thickness and a length of the laminate.

Further, the adhesive layer makes it possible to improve tack of a laminate and a core in the rolling step S21. Further, the core is easily removed by a state of the adhesive layer being changed (such as melting) in the change step S22.

Further, the rolled body forming step may include a cutting step described later. The cutting step may be performed at any stage after the rolling step. Favorably, the cutting step may be performed before, in the middle of, or after the change step.

As described above, the manufacturing method using a core makes it possible to efficiently manufacture a small rDEA, and further makes it possible to prevent a defect such as wrinkles on the manufactured rDEA from being caused. The above-described use of a core is particularly useful for mass production.

These steps are respectively described in detail below.

### (Rolling Step S21)

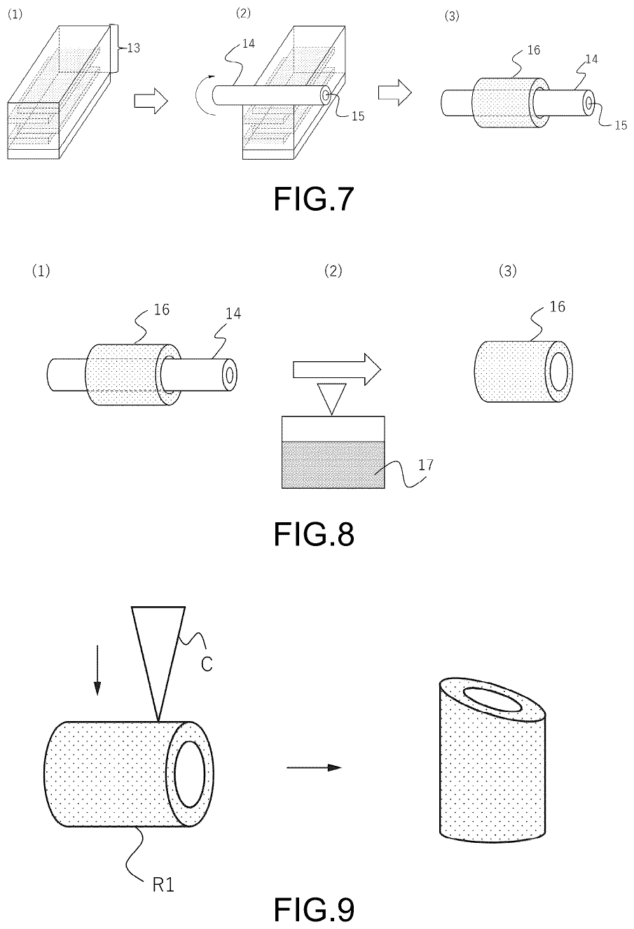

In the rolling step S21, the laminate 13 is rolled around the core 14 to form the rolled body 16, as illustrated in (1) to (3) of FIG. 7. In other words, at least one pair of complimentary electrode layers and a dielectric elastomer layer are rolled around the core 14 in this step. Note that the figure illustrates the laminate 13 such that a thickness of the laminate 13 is emphasized, that is, the figure illustrates the laminate 13 larger than the core 14, in order to achieve a better understanding (in particular, in order to better understand that it is a laminate including an elastomer layer and an electrode layer. It goes without saying that the figure does not indicate an actual dimensional relationship between the laminate and the core. Further, the laminate 13 illustrated in each of (1) and (2) and the laminate 13 illustrated in (3) in the figure have completely different thicknesses. This is also in order to achieve a better understanding. It also goes without saying that such a change in thickness is actually not caused.

In the actual manufacturing method, the thickness of the laminate 13 has the dimension as described above, and is smaller than a diameter of the core 14. Further, there is not a great change in the thickness of the laminate 13 between before and after being rolled, although there is a slight change.

The core 14 may be a core in a substantially columnar form, as illustrated in (2) of FIG. 7.

The core in a substantially columnar form may have a space 15 in a portion corresponding to a central axis of the column. The core may be a hollow core in a substantially columnar form, that is, the core may be in a substantially cylindrical form. As a result, the core is easily affected by liquid or heat, and a change is caused more efficiently in the change step described later.

In the core in a substantially columnar form, the space 15 in a portion corresponding to the central axis of the column may be occupied by a shaft made of a rigid material. The rigid material may be a material, such as metal, resin, or ceramics, that has physical properties of preventing the core from being deformed in the rolling step. This makes it possible to perform the rolling step more stably. The shaft may be pulled out of the core before the change step described later. This results in creating the space 15, and in the liquid easily penetrating the core.

For example, the core 14 may be a fiber material or a porous material. Further, the core 14 may be a metallic material or a plastic material.

Favorably, the core 14 may be a core formed using a material that liquid can penetrate. A fiber material and a porous material are examples of such a material.

The core formed using a fiber material may be a core formed using organic fiber such as pulp, cotton, or plastic fiber (including acrylic fiber, polyester-based fiber, and polyolefin-based fiber), and may be a core formed using paper in particular.

In a favorable embodiment, the material may include a cellulose component, and, for example, the material may be paper. Such a material is favorably used in particular since a core is easily changed when liquid is used to change the core in the change step described later. Further, the use of the material such as paper enables the core to be formed to have a desired degree of rigidity. For example, this makes it easier to perform cutting in the cutting step described later.

In another favorable embodiment, the material may be a resin material. The use of the resin material also enables the core to be formed to have a desired degree of rigidity. For example, this makes it easier to perform cutting in the cutting step described later.

Favorably, an adhesive material may be situated on the outer periphery of the core 14. The adhesive material contributes toward preventing a positional relationship between the core 14 and the laminate 13 from being changed in the rolling step. In other words, the core 14 may include a layer of the adhesive material (hereinafter also referred to as an adhesive layer or a bonding layer) on the outer periphery of the core 14. As a result, a rolled body obtained by the rolling step includes an adhesive layer between the core and the rolled body.

Favorably, the adhesive material is a soluble adhesive material. Particularly favorably, the adhesive material is a soluble adhesive material, and more specifically, the adhesive material may be a soluble adhesive material that is dissolved by being brought into contact with liquid used in the change step described late, or may be a soluble adhesive material that is dissolved by being brought into contact with heat (application of heat) used in the change step described later.

The adhesive material may be provided in advance to the outer periphery of the core 14 before the rolling step is performed, or may be provided to a portion of the surface of the laminate 13 that is brought into contact with the outer periphery of the core 14.

In an embodiment, the adhesive material is favorably a water-soluble adhesive since inexpensive and environment-friendly water can be selected as liquid or solvent that is used in the change step. However, the adhesive material is not limited thereto. The water-soluble adhesive may be an adhesive containing water-soluble polymers. The water-soluble polymer may be a polymer having a hydrophilic group (for example, at least one of a carboxyl group, a sulfonic acid group, an amine group, a hydroxy group, or an amide group) on at least one of a principal chain or a side chain of the polymer. In a favorable embodiment, the water-soluble polymer may polyvinyl alcohol (PVA). The polyvinyl alcohol contributes toward reducing manufacturing costs since the polyvinyl alcohol is inexpensive. As described above, the adhesive layer may contain a water-soluble polymer.

Further, the adhesive may be an acrylic-based adhesive, a silicone-based adhesive, a urethane-based adhesive, or a rubber-based adhesive, but is not limited thereto.

Furthermore, the number of layers of the adhesive is not limited to one, and may be two or more, as described later.

### (Change Step S22)

In the change step S22, a state of the core 14 is changed, as illustrated in (1) and (2) of FIG. 8. The state change may be a change that makes it easy to remove the core 14 from the rolled body 16, and in particular, a change that makes it easy to pull the core 14 out of the rolled body 16. The change may be, for example, a change that makes the core 14 softer, a change that causes the core 14 to be molten, a change that causes the core 14 to be decomposed, a change that makes the core 14 smaller in size, a change that causes the core 14 to shrink, or a change that makes the core 14 thinner. Such a change makes it possible to easily perform the removal step S23 described later.

In an embodiment, the state change may be a state change caused by the core 14 being brought into contact with liquid 17, as illustrated in (2) of FIG. 8. The contact with liquid may be made by the core 14 and rolled body 16 being immersed together in the liquid 17, or by only the core 14 being immersed in the liquid 17. Alternatively, the contact may be made by liquid penetrating the above-described hollow portion (the space 15) of the core 14.

The liquid may penetrate the core 14. More specifically, the liquid is liquid that brings about the change in the core 14. The liquid may be water or aqueous solution, or may be an organic solvent.

When, for example, the liquid is water or aqueous solution, the liquid may have a temperature of 10° C. or more, 20° C. or more, 30° C. or more, 40° C. or more, 50° C. or more, 60° C. or more, 70° C. or more, or 80° C. or more, in order to change the state more quickly. An upper limit of the temperature of the liquid does not necessarily have to be particularly set, and it is sufficient if the temperature is a temperature at which used liquid remains in a liquid state. Further, the temperature of the liquid may be adjusted as appropriate according to, for example, a heat-resistance temperature of a material of the rolled body. For example, silicone-based elastomer has a heat-resistance temperature of from 200° C. to 300° C. The liquid may have a temperature lower than or equal to the heat-resistance temperature of the material of the rolled body.

Alternatively, the state change may be caused by the core 14 being brought into contact with gas (in particular, high-temperature gas). The gas may be, for example, water vapor. The gas may have a temperature of, for example, 100° C. or more, or 110° C. or more. An upper limit of the temperature of the gas does not necessarily have to be particularly set, and the temperature of the gas may also be adjusted as appropriate according to, for example, a heat-resistance temperature of a material of the rolled body. For example, the gas may have a temperature lower than or equal to the heat-resistance temperature of the material of the rolled body.

When, for example, the adhesive layer described above is situated around the core 14, the adhesive layer may be brought into contact with the liquid 17 in the state change. For example, the liquid having penetrated the entirety of the core 14 may be brought into contact with the adhesive layer. The adhesive layer can be dissolved or decomposed by being brought into contact with the liquid. This results in the core 14 being easily removed from the rolled body 16.

In another embodiment, the state change may be a state change caused by the core 14 being heated. In the heating, the core 14 and the rolled body 16 may be heated together, or only the core 14 may be heated (for example, by being brought into contact with a heating medium or by heating a portion of the core that corresponds to an axis of the core).

When, for example, the adhesive layer described above is situated around the core 14, the adhesive layer may be heated in the state change. The adhesive layer is heated to be dissolved, softened, or volatilized. This results in the core 14 being easily removed from the rolled body 16.

### (Removal Step S23)

In the removal step S23, the core 14 is removed from the rolled body 16. As a result, the rolled body 16 without the core 14 is obtained, as illustrated in (3) of FIG. 8. In the change step S22, the state of the core 14 is changed, as described above. Thus, the core 14 is easily removed, and, for example, the core 14 can be pulled out easily.

In the removal step S23, the adhesive layer may also be removed due to the core 14 being removed, or at least a portion of the adhesive layer may remain on an inner-diameter side of the rolled body.

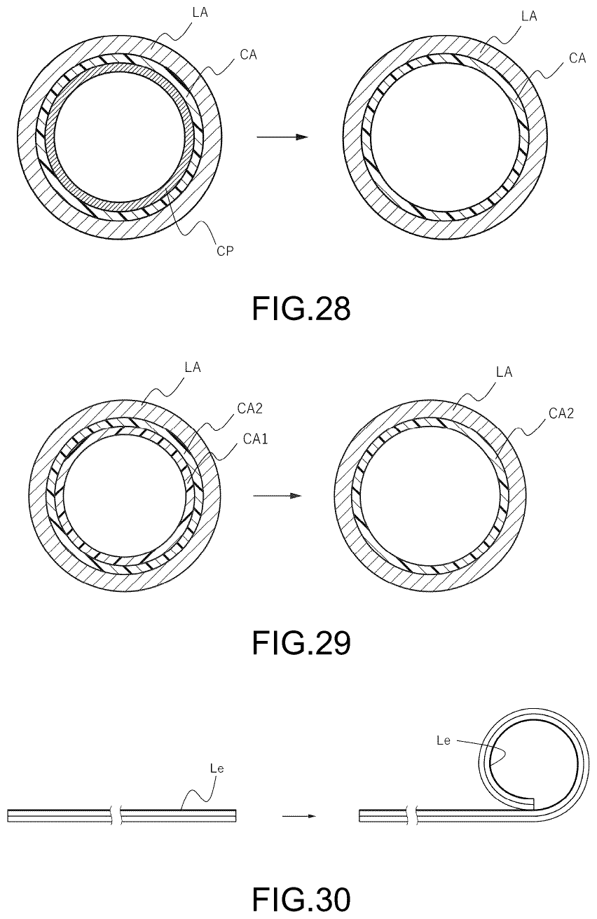

Before the removal step, a rolled body with a core may have a structure including a core CP, an adhesive layer CA that covers an outer periphery of the core CP, and a rolled body LA that covers an outer periphery of the adhesive layer CA, as illustrated, for example, on the left in FIG. 28. Then, the core CP may be removed by the removal step being performed, and all of or a portion of the adhesive layer CA may remain on a surface on an inner-diameter side of the rolled body LA, as illustrated on the right in the figure. It is desirable that, when the adhesive layer CA remains in the rolled body, the adhesive layer be as flexible as the rolled body or be more flexible than the rolled body.

Alternatively, all of the adhesive layer CA may be removed due to the removal step being performed.

Further, the number of the adhesive layers may be one, or may be two or more. In other words, the adhesive layer may include at least two different types of adhesive material layers. For example, a first layer CA1 on the side of a core may be a water-soluble adhesive, and a second layer CA2 on the side of a rolled body may be a silicone-based adhesive, as illustrated on the left in FIG. 29. Note that an illustration of the core is omitted in the figure.

Then, the first layer CA1 is removed together with the core by the removal step being performed. Then, after the removal step, the second layer CA2 may remain on an inner-diameter side of a rolled body LA, as illustrated on the right in the figure.

In this case, liquid used in the change step may be liquid that easily penetrates a material of the first layer or in which the material of the first layer is easily dissolved, and that does not easily penetrate a material of the second layer or in which the material of the second layer is not easily dissolved. For example, an adhesive material of the first layer may be a water-soluble polymer (such as PVA), and an adhesive material of the second layer may be a silicone-based adhesive. In this case, liquid used in the change step may be water or aqueous solution.

When the removal step S23 is performed, an electrode layer may be exposed from the inner-diameter side of the rolled body depending on a configuration of a laminate original sheet. As an example of the laminate original sheet having a minimum configuration, there is a laminate original sheet that includes two dielectric elastomer layers and a pair of electrode layers (that is, two electrode layers), as illustrated in, for example, FIG. 30. When the laminate original sheet having the minimum configuration is rolled up, an electrode layer Le is exposed from an inner-diameter side. Thus, an additional dielectric elastomer layer may be stacked on the exposed electrode layer, in order to avoid the exposure. Alternatively, an electrode layer may be patterned to have a specified shape, in order to avoid such exposure. The avoidance of exposure contributes toward improving the performance of an rDEA.

### (Cutting Step)

The rolled body forming step may further include the cutting step to cut the rolled body 16. For example, the cutting step may be performed after the rolling step S21 and before the change step S22, or may be performed during the change step S22, or may be performed after the change step S22 and before the removal step S23, or may be performed after the removal step S23.

Further, cutting performed in the cutting step may be performed such that the electrode layer may be exposed from a cross-sectional surface in the description above. In this case, the electrode layer does not necessarily have to be exposed in the cut-out step S14 described above.

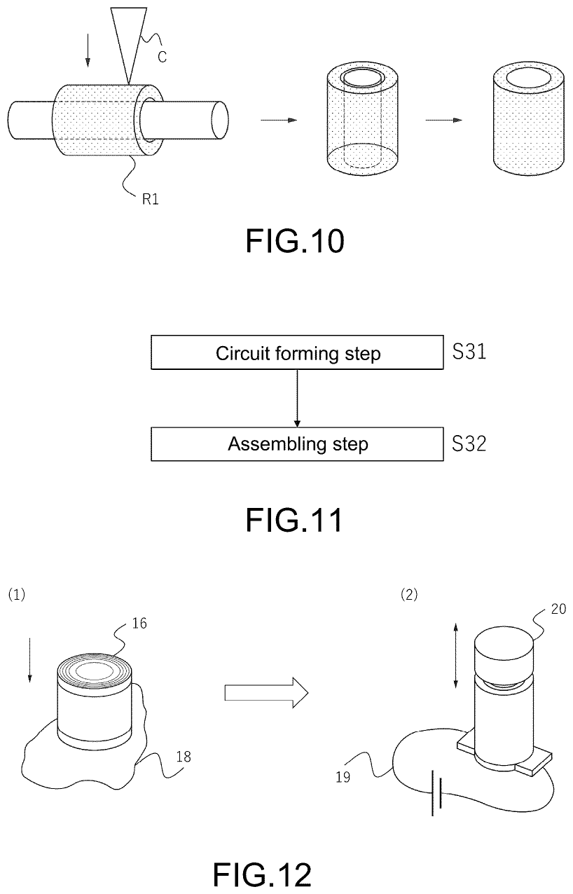

Favorably, the cutting step is performed after the rolling step S21 and before the change step S22. As a result, the rolled body 16 is cut in a state in which the core 14 is situated in a portion corresponding to a central axis of the rolled body 16. Thus, the rolled body 16 is not easily deformed when being cut, and this makes it possible to easily obtain a rolled body having a desired cross-sectional surface. This matter is described below with reference to FIGS. 9 and 10.

FIG. 9 schematically illustrates a rolled body cut when a core is not situated in a portion corresponding to a central axis of the rolled body. As illustrated in the figure, when a rolled body R1 including no core in a portion corresponding to a central axis of the rolled body R1 is cut using a blade of a cutter C, the rolled body R1 is pressed upon cutting since the rolled body R1 is flexible and hollow. As a result, an opening made by cutting and situated at an end of the rolled body R1 is not horizontal.

FIG. 10 schematically illustrates a rolled body cut when a core is situated in a portion corresponding to a central axis of the rolled body. As illustrated in the figure, when a rolled body R2 including a core situated in a portion corresponding to a central axis of the rolled body R2 is cut using the blade of the cutter C, the rolled body R2 is not easily pressed upon cutting since the core is situated in a center portion of the rolled body R2. As a result, an opening made by cutting and situated at an end of the rolled body R2 is horizontal.

When the cutting step described above is performed in a state in which a core is situated inside of a rolled body, that is, when, for example, the cutting step is performed after the rolling step S121 and before the change step S122, as described above, this makes it possible to obtain a rolled body of a good quality.

Favorably, the cutting is performed using an ultrasonic waves cutter. The ultrasonic waves are suitable for cutting a flexible material, and are suitable for cutting a rolled body including an elastomer layer. Further, favorably, a material of a core is paper or a plastic material in order to prevent an edge of a cutter from being chipped.

### 1.5 Modularization Step

In the modularization step, the rolled body is modularized to form an rDEA. In other words, it is sufficient if the rolled body is configured to serve as a DEA module in the modularization step, and this step may be designed as appropriate by those skilled in the art.

The modularization step may include a circuit forming step S31 to incorporate an electrode layer of the rolled body into a specified circuit, and an assembling step S32 to assemble the rolled body into a specified DEA module, as indicated by, for example, a flowchart in FIG. 11.

In the circuit forming step S31, for example, a conductive material (such as a conductive adhesive, a conductive film, or electric wiring) is provided to a surface that is included in the rolled body and from which an electrode is exposed. Then, the rolled body is connected to a circuit using the conductive material.

As illustrated in, for example, FIG. 12, a surface that is included in the rolled body 16 and from which an electrode is exposed is dipped into a conductive adhesive 18. Then, the rolled body is incorporated into a specified separate circuit 19 using the conductive adhesive. Further, the rolled body may be incorporated into any housing 20 for the user's convenience. The rDEA according to the present disclosure may be manufactured, as described above.

Note that the manufacturing method described above is an embodiment according to the present disclosure, and modifications may be made thereto by those skilled in the art as appropriate within the scope of the present disclosure.

### 1.6 Example of Mass Production Process

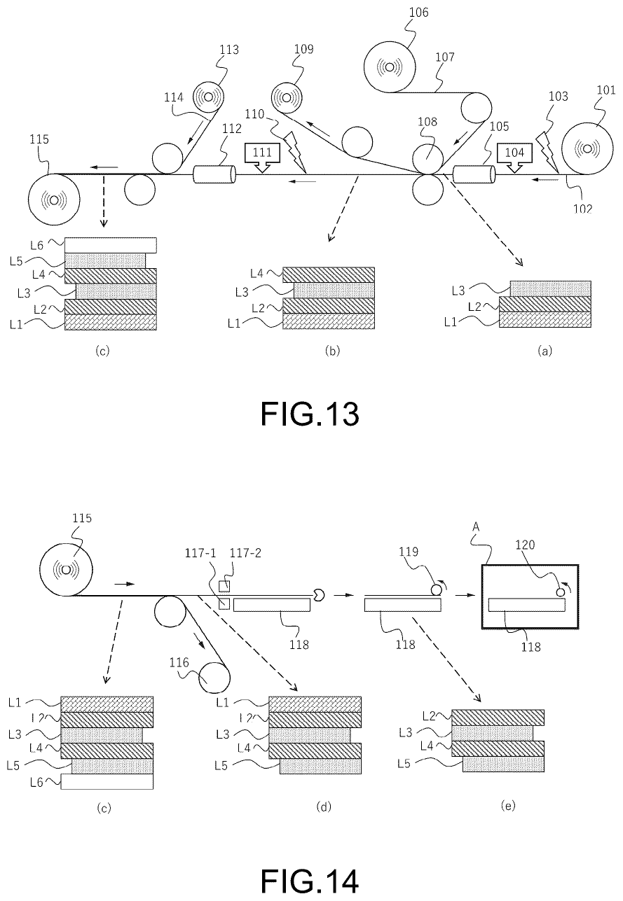

An example of performing the manufacturing method according to the present disclosure in a mass production process is described below with reference to FIGS. 13 to 15.

A laminate 102 including a first removable carrier layer (a base member layer) L1 and an elastomer layer L2 is rolled around a roll 101 illustrated in FIG. 13. The laminate 102 is transported as indicated by an arrow in the figure. Surface activation processing is performed by a surface activation processing apparatus 103 with respect to a surface of the dielectric elastomer layer L2 of the laminate 102 (one of two principal surfaces of the dielectric elastomer layer L2 that is situated opposite to the other principal surface on which the first removable carrier layer L1 is provided). The surface activation processing may be, for example, plasma processing. Thereafter, an electrode layer L3 is printed on the surface of the dielectric elastomer layer L2 by an electrode printing apparatus 104. For example, blow drying is performed by a drying oven 105 after the printing.

Accordingly, a laminate (a) in which the first removable carrier layer L1, the dielectric elastomer layer L2, and the electrode layer L3 are stacked in this order is obtained, as illustrated in (a) of the figure.

A laminate 107 including a dielectric elastomer layer and a second removable carrier layer is rolled around a roll 106 illustrated in the figure. The laminate 107 is supplied as indicated by an arrow in the figure, and then, the dielectric elastomer layer is stacked on the electrode layer L3 of the laminate (a) by a laminator 108. As illustrated in (b) of the figure, a laminate (b) in which the first removable carrier layer L1, the dielectric elastomer layer L2, the electrode layer L3, and a dielectric elastomer layer L4 are stacked in this order is obtained, and the second removable carrier layer is removed from the elastomer layer L4 to be taken up by a roll 109.

The laminator 108 may be a laminator that performs thermal lamination. In other words, the lamination processing may be thermal lamination.

In order to perform the lamination and removal described above, the first removable carrier layer may be less easily removed from the elastomer layer than the second removable carrier layer. In other words, removal strength necessary to remove the first removable carrier layer from the elastomer layer may be higher than removal strength for the second removable carrier layer.

Further, surface activation processing is performed by a surface activation processing apparatus 110 with respect to a surface of the elastomer layer L4 of the laminate (b) (one of two principal surfaces of the elastomer layer L4 that is situated opposite to the other principal surface in contact with the electrode layer L3). The surface activation processing may be, for example, plasma processing. Thereafter, an electrode layer L5 is printed on the surface of the elastomer layer L4 by an electrode printing apparatus 111. For example, blow drying is performed by a drying oven 112 after the printing. After the blow drying, an interlayer sheet 114 supplied by a roll 113 is stacked on the electrode layer L5. The interlayer sheet 114 prevents laminates from being attached to each other when they are taken up by a source roll 115, and may be, for example, interlayer paper. It is sufficient if the interlayer sheet 114 can prevent attachment to the first removable carrier layer, and the interlayer sheet 114 may be selected as appropriate by those skilled in the art.

Accordingly, a laminate (c) in which the first removable carrier layer L1, the elastomer layer L2, the electrode layer L3, the elastomer layer L4, the electrode layer L5, and an interlayer sheet layer L6 are stacked in this order is obtained, as illustrated in (c) of the figure, and the laminate (c) is taken up by the source roll 115. The laminate (c) manufactured as described above is taken up by the source roll 115 and used to manufacture a rolled body.

FIG. 14 schematically illustrates a method for forming a rolled body using the laminate (c). As illustrated in the figure, the laminate (c) is supplied by the source roll 115. Note that the laminate (c) illustrated in FIG. 14 is the same as the laminate (c) illustrated in FIG. 13, although it is turned upside down.

The interlayer sheet layer L6 included in the laminate (c) supplied by the source roll 115 is removed from the electrode layer L5, and the removed interlayer sheet layer L6 is taken up by a roll 116.

The interlayer sheet layer L6 is removed from the laminate (c), and a laminate (d) in which the first removable carrier layer L1, the elastomer layer L2, the electrode layer L3, the elastomer layer L4, and the electrode layer L5 are stacked is obtained, as illustrated in (d) of the figure. The laminate (d) is cut using cutters 117-1 and 117-2 to have a specified size. Then, the laminate (d) having the specified size is placed on a sticking plate 118.

The laminate (d) may be placed on the sticking plate such that the electrode layer L5 is in contact with the sticking plate and the first removable carrier layer L1 is exposed to the air.

Note that this step may be performed such that the elastomer layer L2 is in contact with the sticking plate. In this case, L1 may be removed instead of L6.

Only the first removable carrier layer L1 included in the laminate (d) placed on the sticking plate is taken up by a bar 119 for collecting a carrier layer. As a result, a laminate (e) in which the elastomer layer L2, the electrode layer L3, the elastomer layer L4, and the electrode layer L5 are stacked is obtained, as illustrated in (e) of the figure.

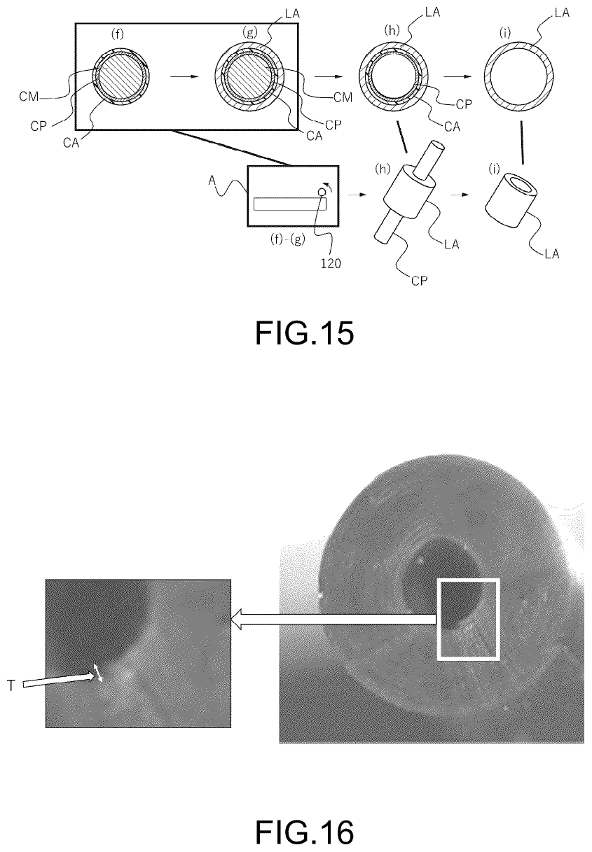

Next, the laminate (e) is rolled around a core 120. (f) and (g) of FIG. 15 respectively schematically illustrate a cross section of the core 120 and a cross section of the rolled body obtained by the rolling around the core.

As illustrated in (f) of the figure, the core 120 may be a core that is in a substantially columnar form and that has a structure in which a paper layer CP and an adhesive layer CA cover around a metallic core CM in this order.

When the laminate (e) is rolled around the core 120, a rolled body LA obtained by the laminate (e) being rolled around the adhesive layer CA multiple times is formed, as illustrated in (g) of the figure. Accordingly, a rolled-body structure according to the present disclosure is obtained. Note that a layer structure in the rolled-body structure is omitted in the figure.

The metallic core CM is removed from a laminate (g). The metallic core CM is in contact with the paper layer CP, and the metallic core CM is easily removed from the paper layer CP.

The removal of the metallic core CM results in obtaining a structure that includes a core of the paper layer CP having a hollow central-axis portion, the adhesive layer CA covering an outer periphery of the paper layer CP, and the rolled body LA covering around the adhesive layer CA, as illustrated in (h) of the figure.

There is also a schematic perspective view of the structure under the cross-sectional view of (h). As shown using the perspective view, the structure may have a configuration in which the rolled body LA is rolled around the core of the paper layer CP.

Next, the structure illustrated in (h) is brought into contact with liquid, such as water or aqueous solution, that penetrates the paper layer CP. This results in making the paper layer CP softer, and this makes it easy to remove the paper layer CP from the rolled body LA.

Further, the liquid is also brought into contact with the adhesive layer CA since the liquid penetrates the paper layer CP. As a result, the adhesive layer CA is dissolved in the liquid or the adhesive layer CA becomes less adhesive. Accordingly, the paper layer CP is easily removed from the rolled body LA due to the adhesive layer CA. Such a change in a state of a core (the paper layer CP and/or the adhesive layer CA) makes it easy to remove the core from the rolled body.

Next, the removal of the paper layer CP results in obtaining the rolled body LA. Note that, as a result of the removal, the adhesive layer CA may also be removed from the rolled body LA. The obtained rolled body LA is illustrated in (i) of the figure. Alternatively, a portion of or all of the adhesive layer CA may remain on an inner-diameter side of the rolled body LA.

The rolled body obtained as described above is connected to a circuit to form an rDEA, as described above.

### 2. Second Embodiment (rDEA)

The present disclosure also provides a rolled dielectric elastomer actuator (rDEA). The rDEA includes a rolled body of a laminate (hereinafter also referred to as a “laminate original sheet”) having a thickness of 200 μm or less.

When the laminate original sheet is made thin, its handling performance upon rolling is made lower, and the laminate original sheet is not rolled appropriately. Thus, the thickness of a laminate original sheet included in an existing rDEA is normally 200 μm or greater, and is, for example, about a 500 μm even if the laminate original sheet is thin.

The inventors have found out that the adoption of the manufacturing method according to the present disclosure, which is described in 1. above, that is, especially the use of the core described above makes it possible to manufacture an rDEA with no defect such as wrinkles even if a laminate original sheet has a thickness of 200 μm or less.

As described above, the thickness may be 200 μm or less, more favorably 180 μm or less, and much more favorably 160 μm or less, 140 μm or less, 120 μm or less, or 100 μm or less.

The thickness may be favorably 5 μm or greater, more favorably 10 μm or greater, and much more favorably 15 μm or greater, 20 μm or greater, 25 μm or greater, or 30 μm or greater.

FIG. 16 illustrates pictures of an rDEA manufactured by the inventors. The figure illustrates, on the right, a picture of an end surface of a rolled body of the rDEA, and on the left, there is an enlarged view of a portion, in the picture, that is boxed using white lines. An arrow in the picture on the left indicates a thickness T of a laminate original sheet. The thickness T is less than 40 μm. The manufacturing method according to the present disclosure makes it possible to obtain a good-quality rolled body with no defect such as wrinkles even if such a very thin laminate original sheet is used.

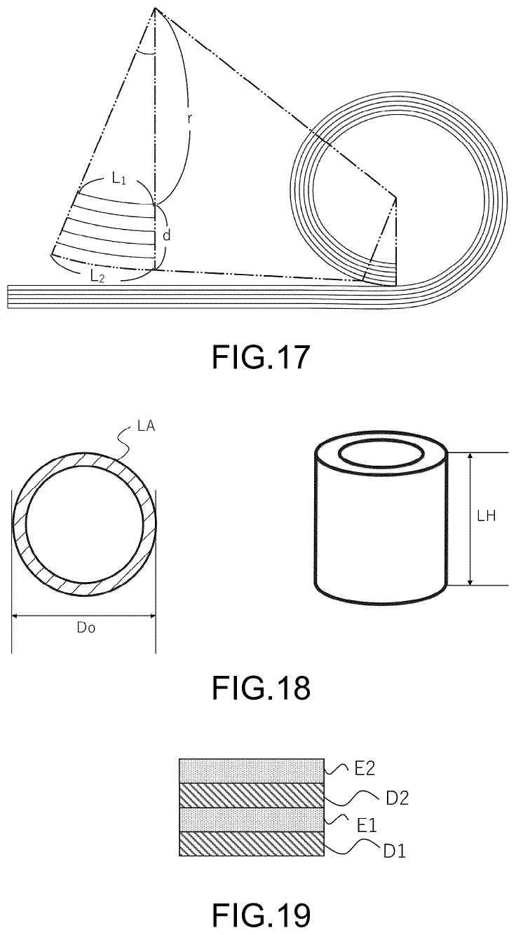

Further, a rolled body of a very thin laminate original sheet is more useful in preventing an issue related to dielectric strength from being caused, compared to when a thick laminate original sheet is used. This matter is described with reference to FIG. 17.

An rDEA has a structure in which a laminate including an elastomer layer and an electrode layer is rolled. Thus, an outer-diameter-side portion of a rolled body (an outer-peripheral-side portion of the rolled body) is more stretched than an inner-diameter-side portion of the rolled body (a portion, of the rolled body, that is situated close to a central axis of the rolled body). This may result in causing, for example, an issue such as a decrease in dielectric strength.

L₁ and L₂ have the following relationship when a length on the inner-diameter side is represented by L₁, a length on the outer-diameter side is represented by L₂, an inner diameter of a hollow portion of the rolled body is represented by 2r, and a thickness of the laminate original sheet is represented by d, as illustrated in FIG. 17.

$$\frac{{L}_{2}}{{L}_{1}} \approx 1 + \frac{d}{r} \qquad [ Math . 2 ]$$

For example, the stretching is performed such that L₂ is twice as large as L₁ when the inner diameter is 1 mm and the original sheet has a thickness of 0.5 mm (500 μm).

On the other hand, the stretching is performed such that L₂ is 1.08-fold as large as L₁ when the inner diameter is 1 mm and the original sheet has a thickness of 0.04 mm (40 μm).

The manufacturing method according to the present disclosure enables a very thin laminate original sheet having a thickness of 200 μm or less to be rolled with no defect, as described above. Thus, a laminate original sheet of an rDEA provided by the present disclosure has a thickness of 200 μm or less. This makes it possible to achieve a small ratio between a length on the outer-diameter side and a length on the inner-dimeter side. This prevents issues, such as a decrease in dielectric strength, that are caused due to a difference between the lengths.

As described above, a ratio (L₂/L₁) between the outer-diameter-side length L₂ of a laminate original sheet included in an rDEA according to the present disclosure and the inner-diameter-side length L₁ of the laminate original sheet may be, for example, 1.5 or less, favorably 1.4 or less, and more favorably 1.3 or less, 1.2 or less, or 1.1 or less.

Note that, normally, the outer-diameter-side length L₂ is greater than or equal to the inner-diameter-side length L₁, and the ratio thereof may be greater than or equal to 1.00.

The inner diameter 2r of the rolled body of the rDEA according to the present disclosure (that is, a diameter of a hollow portion of the rolled body) may be, for example, 0.1 mm or greater, favorably 0.2 mm or greater, and more favorably 0.3 mm or greater, 0.4 mm or greater, or 0.5 mm or greater.

The inner diameter 2r may be, for example, 10 mm or less, favorably 9 mm or less, more favorably 8 mm or less, 7 mm or less, or 6 mm or less, and much more favorably 5 mm or less, 4 mm or less, or 3 mm or less.

When a hollow portion of the rDEA according to the present disclosure has a small inner diameter, as described above, this makes it possible to make the entirety of the rDEA smaller in size.

Further, such an rDEA having a small inner diameter can be obtained by using a core and by changing the core to remove the core, as described above regarding the manufacturing method. In the past, it has been very difficult to manufacture such an rDEA having a small inner diameter.

An outer diameter of the rolled body of the rDEA according to the present disclosure corresponds to a diameter Do of a circle defined by an outer peripheral surface (an outermost layer) of the rolled body LA, as illustrated in FIG. 18.

The outer diameter may be, for example, 1 mm or greater, 2 mm or greater, or 3 mm or greater.

The outer diameter may be, for example, 15 mm or less, favorably 10 mm or less, more favorably 9 mm or less, and much more favorably 8 mm or less, 7 mm or less, or 6 mm or less.

In an embodiment, the outer diameter may be 5 mm or less, or 4 mm or less. The manufacturing method according to the present disclosure also makes it possible to obtain an rDEA that includes such a rolled body having a very small outer diameter.

When the rolled body of the rDEA according to the present disclosure has a small outer diameter, as described above, the entirety of the rDEA can be made smaller in size, and further, an apparatus into which the rDEA is incorporated can also be made smaller in size, or a space used to incorporate other parts into an apparatus is secured as a result of making the rDEA smaller in size.

The rolled body of the rDEA according to the present disclosure may have a mass of, for example, 10 mg or greater, 20 mg or greater, or 30 mg or greater.

The mass may be, for example, 1000 mg or less, favorably 900 mg or less, more favorably 800 mg or less, and much more favorably 700 mg or less, 600 mg or less, or 500 mg or less.

In an embodiment, the mass may be 400 mg or less, 300 mm or less, 200 mg or less, 150 mg or less, or 100 mg or less. The manufacturing method according to the present disclosure also makes it possible to obtain an rDEA that includes such a very light rolled body.

When the rolled body of the rDEA according to the present disclosure is light in weight, as described above, the mass of the entirety of the rDEA can be made smaller, and further, the mass of an apparatus into which the rDEA is incorporated can also be made smaller.

A length LH of the rolled body of the rDEA according to the present disclosure in a direction of a rolling axis of the rolled body corresponds to a height LH of a columnar form of the rolled body LA, as illustrated in FIG. 18.

The length LH may be, for example, 2 mm or greater, 5 mm or greater, 10 mm or greater, or 15 mm or greater.

The length LH may be, for example, 50 mm or less, favorably 45 mm or less, and more favorably 40 mm or less.

In an embodiment, the length LH may be 30 mm or less, 25 mm or less, or 20 mm or less. The manufacturing method according to the present disclosure also makes it possible to obtain an rDEA that includes such a small rolled body.

A laminate original sheet of the rDEA according to the present disclosure is a laminate including at least one pair of complimentary electrode layers and a dielectric elastomer layer, as described in 1. above, that is, a laminate sheet that is rolled to form the rolled body. The laminate original sheet may be a sheet that has a lamination structure in which a dielectric elastomer layer D1, an electrode layer E1, a dielectric elastomer layer D1, and an electrode layer E2 are stacked in this order, as illustrated in, for example, FIG. 19. The sheet is rolled to obtain a rolled body. Materials of the dielectric elastomer layers and the electrode layer may be materials as described in 1. above.

Further, at least one additional dielectric elastomer layer and/or at least one additional electrode layer may be stacked on the lamination structure such that an electrode layer and a dielectric elastomer layer are stacked alternately, as described in 1. above.

In addition to the rolled body, the rDEA according to the present disclosure may include a circuit to which an electrode layer in the rolled body is electrically connected. FIGS. 2 and 12 each schematically illustrate an rDEA with the circuit. A configuration of the circuit may be designed as appropriate by those skilled in the art.

The rDEA according to the present disclosure may further include a housing that accommodates therein the rolled body. The housing may be configured to have a structure that can vary according to expansion and shrinkage of the rolled body (especially expansion and shrinkage of the rolled body in a direction of an axis of the rolled body). For example, the housing may be in a columnar form, as in the case of the housing 20 illustrated in FIG. 12. Further, the housing may be configured to expand and shrink in a direction of a height of the column, as indicated by an arrow illustrated next to the housing 20 in the figure. In order to have such a configuration, the housing may be divided into at least two portions, or may be formed using a material that can expand and shrink.

### 3. Third Embodiment (Apparatus or System)

The present disclosure provides an apparatus that includes an rDEA according to the present disclosure. The apparatus may be, for example, an operation input apparatus, a transducer, or an endoscope apparatus. Further, the present disclosure also provides an information processing system that includes the rDEA. The rDEA according to the present disclosure can be made smaller in size and can also be made lighter in weight, as described above. Further, the rDEA according to the present disclosure has no defect such as wrinkles, has a good quality, and can be mass-produced. The rDEA according to the present disclosure can be used in various apparatuses and systems.

The apparatus may be an operation input apparatus. The operation input apparatus includes, for example, a movable member that is moved by operation performed by a user, and a dielectric elastomer actuator that controls movability of the movable member. The dielectric elastomer actuator is the rDEA manufactured by the manufacturing method described in 1. above, or the rDEA described in 2. above.

The operation input apparatus is configured such that the rDEA controls the movability of the movable member. The operation input apparatus having such a configuration can adjust a feeling of operation quietly at high speed, and can be easily made smaller in size and lighter in weight. Further, the rDEA exhibits a high rate of deformation and a large amount of energy generated per unit weight. This makes it possible to control a feeling of an operation of the movable member efficiently.

The operation input apparatus may be an operation input apparatus of, for example, a button type, a wheel type, a ball type, or a joystick type, but is not limited thereto. Examples of these types will be described below. Further, the operation input apparatus according to the present disclosure may be used as, for example, a haptic device since the operation input apparatus can provide various kinds of feelings to the user.

The rDEA may control the movability to adjust a feeling of resistance to movement of the movable member. This enables a user who is operating the operation input apparatus (especially the movable member) to perceive various kinds of feelings of resistance upon the operation, that is, this makes it possible to provide various kinds of feelings (such as a sense of touch) to the user. For example, an interesting or exciting experience can be provided to the user.

For example, the operation input apparatus according to the present disclosure may be, for example, a controller of a game machine, or an element (such as a button unit) included in a controller of a game machine. The present disclosure makes it possible to control movability of a movable member quietly at high speed. In addition, the number of parts necessary to control movability of a movable member according to the present disclosure is small. Thus, the apparatus can be made smaller in size and lighter in weight. Further, a configuration of the apparatus can be made simpler. These advantages are provided significantly especially when the present disclosure is applied to a controller of a game machine.

### 3.1 Example of Configuration of Apparatus (Button)

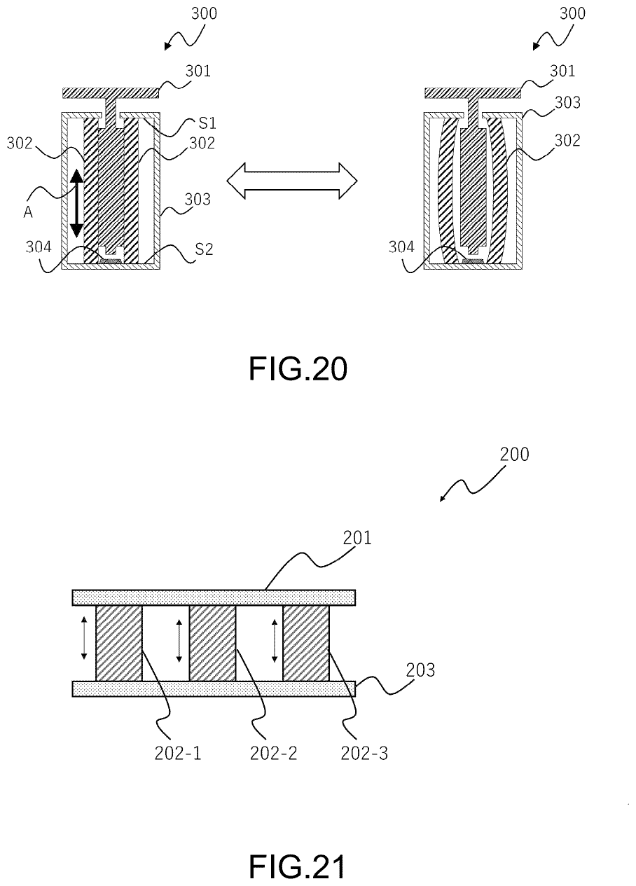

The operation input apparatus according to the present disclosure may be configured such that the movability of the movable member is controlled in response to a change in an inner diameter of the rDEA due to expansion and shrinkage of the rDEA. This example is described below with reference to FIG. 20.

On the left in the figure, there is a schematic cross-sectional diagram of an operation input apparatus 300 according to the present disclosure. The operation input apparatus 300 includes a movable member 301 that receives a user operation, and an rDEA 302 that controls movability of the movable member. The operation input apparatus further includes a housing 303 that accommodates therein the rDEA 302, and a movement detection sensor 304 that detects movement of the movable member 301. Those structural elements are described below.

The rDEA 302 is configured to control the movability of the movable member 301 using a change in an inner diameter of a cylindrical form of the rDEA 302. The movable member 301 is arranged in a hollow portion of the rDEA 302.

The rDEA 302 is fixed to two inner surfaces S1 and S2 situated inside of the housing 303. The rDEA 302 is configured to extend in a direction of an arrow A in the figure (a direction of an axis of the cylinder) due to voltage being applied to the rDEA 302.

On the left in the figure, voltage is not applied to the rDEA 302. In this case, the rDEA 302 is in contact with the movable member 301.

The rDEA 302 extends in the direction of the arrow A in the figure due to voltage being applied to the rDEA 302. However, a distance between the inner surfaces S1 and S2 is constant, and the DEA 302 is fixed to the inner surfaces S1 and S2. Thus, there is a change in the inner diameter of the rDEA 302, as illustrated on the right in the figure. In other words, the inner diameter of the rDEA 302 is increased due to the application of voltage, and this results in the rDEA 302 becoming out of contact with the movable member 301 (or this results in a reduction in a pressure of contact of the rDEA 302 with the movable member 301). As a result, no friction is caused between the movable member 301 and the rDEA 302 (or there is a reduction in friction), and this results in a reduction in a feeling of resistance that is perceived upon operation of the movable member 301.

3.2 Example of Configuration of Apparatus (Plurality of rDEAs)

The operation input apparatus according to the present disclosure may include one rDEA or a plurality of rDEAs. When, for example, the plurality of rDEAs is controlled in a separate manner, this makes it possible to produce various kinds of feelings. Further, the rDEA according to the present disclosure is small in size and light in weight. Thus, the plurality of rDEAs can be arranged in a small space, and further, the apparatus itself can be made lighter in weight. An example of an operation input apparatus including a plurality of rDEAs is described below with reference to FIG. 21.

The figure schematically illustrates where rDEAs are arranged in an operation input apparatus 200. The operation input apparatus includes a movable member 201, a plurality of rDEAs 202-1, 202-2, and 202-3, and a housing 203. Further, the operation input apparatus includes a sensor (not illustrated) that detects movement of the movable member 201.

The rDEAs 202-1 to 202-3 are configured to be capable of extending and shrinking independently of each other in directions of respective arrows illustrated in the figure. When the extensions and shrinkages of the rDEAs 202-1 to 202-3 are controlled in a separate manner, this makes it possible to variously change a feeling perceived by a user upon pressing the movable member 201.

When, for example, voltage is applied to one of or two of the three rDEAs and voltage is not applied to the other two of or the other one of the rDEAs, this makes it possible to change movability of the movable member 201 more variously, compared to when voltage is applied to all of the rDEAs or voltage is not applied to any of the rDEAs.

Further, the operation input apparatus 200 in the figure is configured such that three rDEAs control movability of one movable member. However, the number of rDEAs may be four or more.

Furthermore, in the operation input apparatus 200 in the figure, three rDEAs are arranged one-dimensionally. However, a plurality of rDEAs may be arranged two-dimensionally.

### 3.3 Example of Configuration of Apparatus (Transducer)

The present disclosure also provides a transducer that includes the rDEA according to the present disclosure. The transducer may be configured to sense deformation of the IDEA on the basis of, for example, a change in capacitance due to the deformation.

When, for example, an rDEA (especially a rolled body) extends, a dielectric elastomer between electrode layers is made thinner, and this results in an increase in the area covered by the electrode layers. This increase in the area results in an increase in capacitance. When, conversely, the rDEA (especially the rolled body) extends and shrinks, the dielectric elastomer between the electrode layers is made thicker, and this results in a reduction in the area covered by the electrode layers. This reduction in the area results in a reduction in capacitance. In other words, these electrode layers are considered a variable capacitor.

Thus, when the rDEA according to the present disclosure includes a pair of electrodes used to measure a change (that is, an increase or a reduction) in capacitance, this makes it possible to detect a deformation of the rDEA or to quantify a degree of the deformation of the rDEA.

The pair of electrodes used to detect the change in capacitance may be electrically connected to the electrode layers described above. In other words, electrodes included in the pair of electrodes may be respectively electrically connected to two electrode layers between which a dielectric elastomer layer is situated. Further, the pair of electrodes may be electrically connected to a specified capacitance detection circuit. In other words, in addition to the rDEA according to the present disclosure, the transducer may include a capacitance detection circuit connected to electrode layers included in the rDEA. The circuit may be connected to the electrode layers of the rDEA through the pair of electrodes.

Further, the present disclosure also provides a transducer that includes a rolled body according to the present disclosure. The transducer may include the rolled body, and a capacitance detection circuit electrically connected to the rolled body (especially electrode layers). The transducer may be configured to perform sensing as described above. The transducer may be configured to perform sensing as described above and to operate as an actuator, or the transducer may only perform sensing without operating an actuator.

### 3.4 Example of Configuration of Apparatus (Endoscope Apparatus)

The present disclosure also provides an endoscope apparatus including the rDEA according to the present disclosure. For example, a tip camera portion of a videoscope included in the endoscope apparatus may include the rDEA according to the present disclosure. The rDEA may be configured to change a form of the tip camera portion. The rDEA according to the present disclosure is small in size and light in weight, and thus is suitable for being provided to the tip camera portion. For example, the rDEA may be configured such that the tip camera portion extends and shrinks, or the rDEA may be configured such that the tip camera portion is bent in a desired direction.

### 3.5 Example of Configuration of Information Processing System

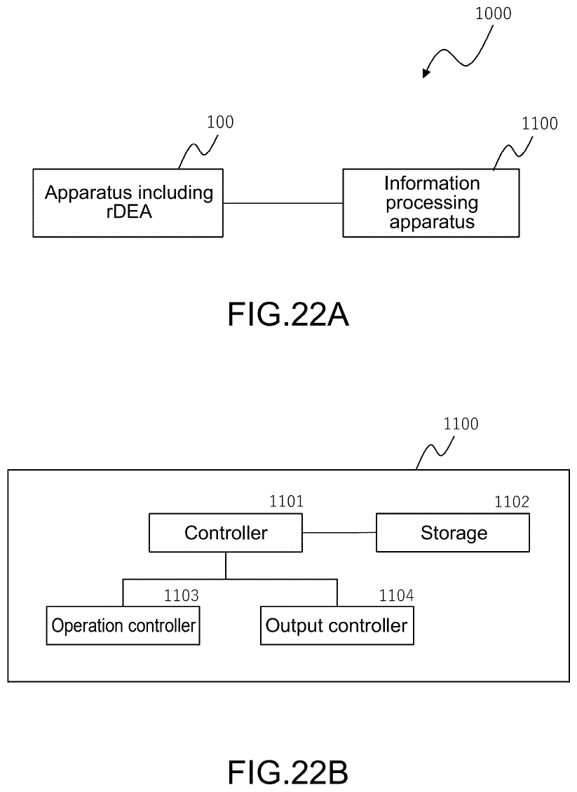

The present disclosure also provides an information processing system that includes the apparatus described above (especially the operation input apparatus, the transducer, or the endoscope apparatus). An example of the information processing system is described with reference to FIGS. 22A and 22B.

In an embodiment, an information processing system 1000 according to the present disclosure may include an information processing apparatus 1100 in addition to an apparatus (especially the operation input apparatus) 100 according to the present disclosure, where the information processing apparatus 1100 is configured to transmit, to the apparatus 100, a signal (an electric signal) used to control an rDEA. The information processing apparatus 1100 may control the apparatus 100 such that a specified voltage is applied to a DEA 102 of the apparatus 100.

In another embodiment, the information processing system 1000 according to the present disclosure may include the information processing apparatus 1100 in addition to the apparatus 100 (especially the transducer) according to the present disclosure, where the information processing apparatus 1100 is configured to receive, from the apparatus 100, a signal (an electric signal) related to deformation of an rDEA (a change in capacitance in particular). The information processing apparatus 1100 may perform specified information processing according to the signal received from the apparatus 100.

Further, the information processing apparatus 1100 may be configured to receive a signal (an electric signal) generated by operation performed by a user on the apparatus 100 (the operation input apparatus in particular). The signal may be a signal generated by, for example, a movement detection sensor 104 detecting movement of a movable member 101.

The information processing apparatus 1100 and the apparatus 100 may be connected to each other by any connection method, and may be connected to each other through, for example, a USB cable. A signal of which transmission or reception is performed between the information processing apparatus 1100 and the apparatus 100 may be set as appropriate by those skilled in the art.

In an embodiment, the information processing apparatus 1100 may be, for example, an information processing apparatus that can execute a game, and may be what is called a game machine. In this case, the apparatus 100 may be a controller of the game machine.

A configuration of the information processing apparatus 1100 may be set as appropriate by those skilled in the art, and the information processing apparatus 1100 may include, for example, a controller 1101, a storage 1102, an operation controller 1103, and an output controller 1104, as illustrated in FIG. 20B. Note that, for example, functions of the controller 1101, the operation controller 1103, and the output controller 1104 may be integrated into a single controller.

The controller 1101 may be a program control device such as a CPU and/or a GPU, and may operate in accordance with a program stored in the storage 1102. When, for example, the information processing apparatus 1100 is a game machine, the controller 1101 may be configured to execute an application of a game. When the controller 1101 receives, from the operation controller 1103, a signal input by operation performed by a user on the operation input apparatus 100, the controller 1101 may perform specified processing on the basis of the signal.

The storage 1102 may be, for example, a memory device or a hard disk drive, and may store therein a program executed by the controller 1101.

The operation controller 1103 is connected to the operation input apparatus 100 by a specified connection method (to be capable of communicating with the operation input apparatus 100, for example, wirelessly or by wire). The operation controller 1103 receives, from the operation input apparatus 100, a signal indicating details of operation performed by a user on the operation input apparatus 100, and transmits the signal to the controller 1101.

The output controller 1104 may be connected to a display device of a television, a monitor, or a head-mounted display, and outputs a signal of sound and/or a video to the display device according to an instruction input by the controller 1101.

### 4. Examples

More specific examples of the present disclosure are described using examples described below. The present disclosure is not limited to the examples described below.

### 4.1 Manufacturing of Rolled Body

### (Laminate Forming Step)

A silicone-based dielectric elastomer material was applied to a PET release base member and cured to form a dielectric elastomer layer. A conductive ink (VC102, CHASM) containing carbon nanotube was applied to the dielectric elastomer layer using screen printing and cured to form an electrode layer. Accordingly, an elastomer film obtained by stacking the electrode layer was formed.

The two elastomer films were produced. The elastomer films overlapped each other, and were heat pressed to be attached to each other. Accordingly, a laminate (hereinafter also referred to as a “laminate original sheet”) including a pair of complimentary electrode layers and an elastomer layer was formed.

The laminate had a thickness of less than 40 μm.

### (Rolled Body Forming Step)

Four types of cores given in Table 1 indicated below were provided. A water-soluble double-sided tape (the water-soluble double-sided adhesive tape 57-899, Clover) was attached to an outer periphery of each of the cores. The double-sided tape contained water-soluble polymers PVA as an adhesive layer.

TABLE 1
Core

| Type of core | Maker | Product number, Size | Change step |
|---|---|---|---|
| Heat shrink tube | Sumitomo Electric | F4(Z), Outer diameter | Heated for 5 minutes |
| | Industries, Ltd. | of 1 mm | at 110° C. |
| Hollow paper | Kaoru Kogyo | AG1326, Outer | Stirring hot water |
| tube | | diameter of 3 mm | for 5 minutes |
| Paper string | Hakoseko Kobo | 11016, Outer | Stirring hot water |
| | | diameter of 1 mm | for 30 minutes |
| Paper-wrapped | Sunrise | #18, Outer | Stirring hot water |
| wire | | diameter of 0.8 mm | for 60 minutes |

The laminate original sheet was rolled around the core to which the double-sided tape was attached. Accordingly, a rolled body was obtained. Note that the rolling can be performed by pressing a core against a surface of the laminate original sheet and by rolling the core. Further, conversely, the rolling may be performed by rolling the laminate original sheet around a fixed core.

None of the rolled bodies obtained as described above had wrinkles.

### (Change Step)

The rolled body for which a heat shrink tube was used as a core was heated in the air on the condition given in the item of “Change step” in Table 1 above.

The rolled body for which a hollow paper tube, a paper string, or a paper-wrapped wire was used as a core was immersed in water on the condition given in the item of “Change step” in Table 1 above. Note that a temperature of hot water was about 90° C.

Accordingly, a state of each core was changed.

### (Removal Step)

After the change step, the cores were pulled out of the respective rolled bodies. A time that elapsed before it became possible to pull out each of the cores was as given in the item of “Change step” in Table 1 above.

When a paper-wrapped wire was used as a core, it took 60 minutes before it became possible to pull out the core. When a paper string was used as a core, it took 30 minutes before it became possible to pull out the core, and when a hollow paper tube was used as a core, it took 5 minutes before it became possible to pull out the core.

These results show that it is desirable that a core of an immersed rolled body be made of a fiber material or porous material that liquid penetrates easily. It is conceivable that such a material could cause liquid to penetrate a core rapidly due to capillary effect or a difference in osmotic pressure.

Further, it became possible to pull out a hollow paper tube earlier than a paper string. In other words, it is desirable that the core be hollow in the change step.

### 4.2 Manufacturing of Rolled Bodies in Various Sizes

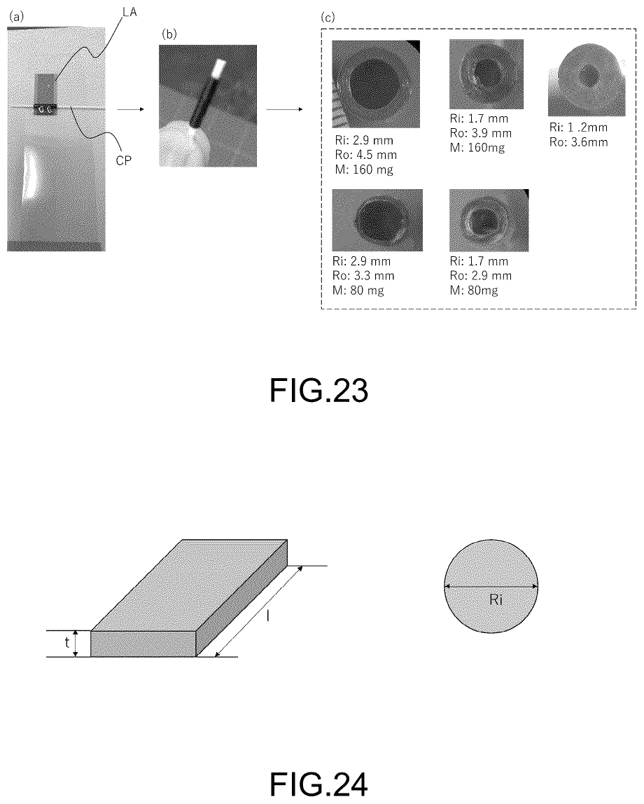

Rolled bodies in various sizes were manufactured using hollow paper tubes as cores. The manufacturing method described in 4.1 above was adopted. FIG. 23 illustrates pictures showing states in respective stages of the manufacturing method.

(a) of the figure is a picture showing a state in which a laminate original sheet is being rolled. As shown by the picture, a laminate original sheet LA was rolled around a hollow paper tube CP.

(b) of the figure is a picture of a rolled body rolled around a core.

The rolled body having a core and obtained as described above was immersed in hot water (90° C.) for about five minutes, and a state of the core was changed. After the change, the core was pulled out of the rolled body. Accordingly, hollow rolled bodies in various sizes were obtained.

(c) of the figure illustrates pictures of cross-sectional surfaces of five types of rolled bodies. In the figure, Ri represents an inner diameter of each rolled body. Ro represents an outer diameter of the rolled body. M represents a mass.

As described above, a small and light rolled body can be manufactured by performing the change step and the pull-out step.

4.3 Manufacturing and Evaluation of rDEA
(Size of Rolled Body of rDEA)

An inner diameter of a hollow portion of a rolled body of an rDEA coincides an outer diameter of a core. Further, a final size of the rolled body of the rDEA is determined by a length of a laminate original sheet in a rolling direction and a thickness of the laminate original sheet. Note that a height of the rDEA coincides a width of the laminate original sheet (a size in a direction vertical to the rolling direction).

### (Generated Force)

A generated force F of an rDEA is obtained using a formula indicated below.

$$F \approx \frac{1}{2} {{ε}_{p} ( \frac{V}{d} )}^{2} S = C \times {V}^{2} \qquad [ Math . 3 ]$$

In the formula, Ep represents a dielectric constant of a dielectric elastomer layer, V represents an applied voltage, d represents a thickness of the dielectric elastomer layer, and S represents the area of a cross section of the rDEA. Further, C on the rightmost side represents a constant obtained by integrating terms based on physical properties of the rDEA.

### (Size)

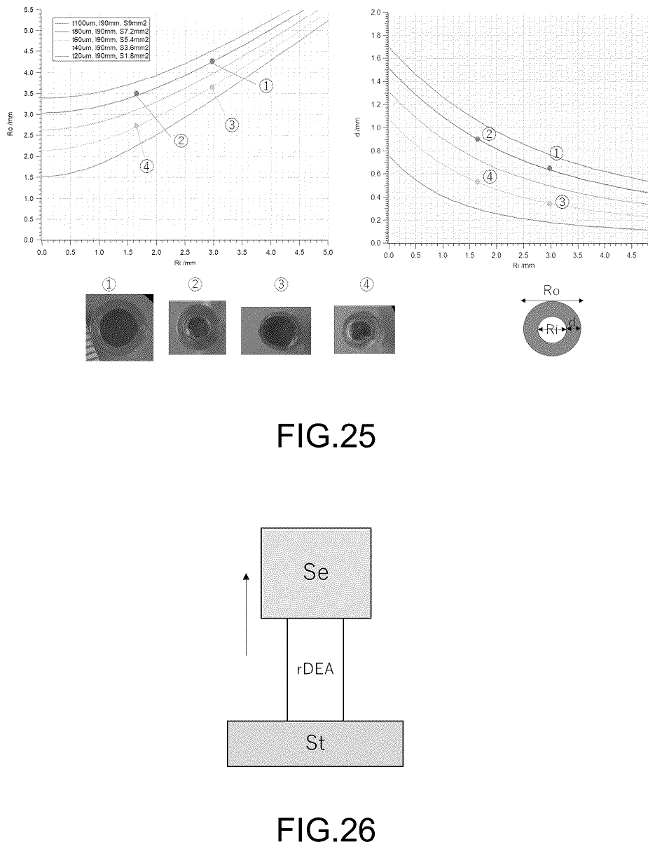

It is assumed that, from among dimensions of a laminate original sheet, a thickness of the laminate original sheet is t, and a length of the laminate original sheet in a rolling direction is 1, as illustrated on the left in FIG. 24. Further, it is assumed that an outer diameter in a cross section of a core (an adhesive layer is also included if the adhesive layer exists) is Ri, as illustrated on the right in the figure. In this case, a size of a rolled body of an rDEA (the inner diameter Ri, the outer diameter Ro, and the thickness d. Refer to a schematic diagram on the lower right in FIG. 25.) can be controlled by the size (the thickness t and the length 1) of the laminate original sheet and the outer diameter Ri of the core.

The inner diameter Ri of the rolled body of the rDEA coincides the outer diameter Ri of the core.

The outer diameter Ro of the rolled body of the rDEA is obtained using a formula indicated below.

$${R}_{o} = \sqrt{\frac{4 lt}{π} + {R}_{i}^{2}} \qquad [ Math . 4 ]$$

The thickness d of the rolled body of the rDEA is obtained using a formula indicated below.

$$d = \frac{1}{2} \sqrt{\frac{4 lt}{π} + {R}_{i}^{2}} - \frac{{R}_{i}}{2} \qquad [ Math . 5 ]$$

With respect to five patterns with specific thicknesses t and specific lengths 1, FIG. 25 illustrates a graph in which a relationship of Ro with Ri is given and a graph in which a relationship of d with Ri is given. The graphs show that Ri, Ro, and d of each of actually manufactured rolled bodies 1 to 4 of rDEAs are consistent with the formulas described above, where the respective rolled bodies are in four pictures in a lower portion of the figure.

### (Measurement of Generated Force)

The manufactured rolled body (the rolled body in the picture with a circled number two in FIG. 25) was connected to a circuit to manufacture an rDEA. A generated force generated by voltage being applied to the rDEA was measured. Specifically, the generated force generated when the applied voltage is changed such as 100 V, 200 V, and 300 V was measured using a force sensor. As illustrated in a schematic diagram of a measurement system in FIG. 26, the measurement was performed by applying voltage to the rDEA arranged on a stage St and by measuring a generated force using a force sensor Se (USLG25, Tec Gihan Co., Ltd.), where the generated force is generated in a direction of an arrow in the figure (a direction in which a cylindrical form of the rolled body extends) due to the application of voltage.

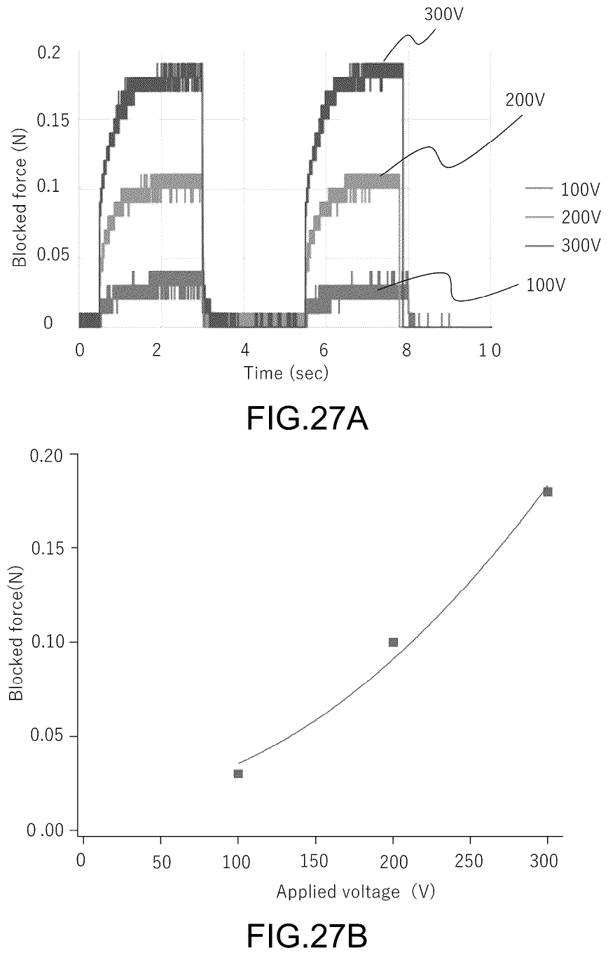

FIG. 27A illustrates a result of the measurement. The figure illustrates a temporal change (Time) in a generated force (Blocked force) when voltages of 100 V, 200 V, and 300 V are applied with a square wave at 0.2 Hz. The measurement result shows that a generated force depending on voltage is generated, as illustrated in the figure.

Further, FIG. 27B illustrates a relationship between an applied voltage and a generated force (Blocked force). In the figure, a dot represents a data point, and a curve represents an approximate curve. The approximate curve shows that a relationship between a generated force and the square of voltage can be generally calculated, as indicated below.

$$F \approx 1.85 \times {10}^{- 6} \times {V}^{2} \qquad [ Math . 6 ]$$

As can be seen from the description above, the rDEA according to the present disclosure can control a generated force by controlling voltage.

The present disclosure may take the following configurations.

[1] A method for manufacturing a rolled dielectric elastomer actuator, the manufacturing method including:
a rolling step to roll at least one pair of complimentary electrode layers and a dielectric elastomer layer around a core to obtain a rolled body;
a change step to change a state of the core after the rolling step; and
a removal step to remove the core from the rolled body after the change step.

[2] The manufacturing method according to [1], in which the core is a core in a substantially columnar form.

[3] The manufacturing method according to [1] or [2], in which the core is a core that is in a substantially columnar form and formed using a material that liquid penetrates successfully.

[4] The manufacturing method according to any one of [1] to [3], in which
the core is a core that is in a substantially columnar form and that includes a fiber material or a porous material.

[5] The manufacturing method according to any one of [1] to [4], in which
the core is a hollow core in a substantially columnar form.

[6] The manufacturing method according to any one of [1] to [5], further including
a cutting step to cut the rolled body obtained by the rolling around the core, such that a complimentary electrode layer of the at least one pair of complimentary electrode layers is exposed.

[7] The manufacturing method according to any one of [1] to [6], in which
the rolled body obtained by the rolling step includes an adhesive layer between the core and the rolled body.

[8] The manufacturing method according to [7], in which
the adhesive layer contains water-soluble polymers.

[9] The manufacturing method according to any one of [1] to [8], in which
the change step includes bringing the core into contact with liquid or heating the core.

The manufacturing method according to any one of [1] to [9], in which
the change step includes bringing the core into contact with liquid, and
the liquid penetrates the core.

[11] A dielectric elastomer actuator, including
a rolled body of a laminate including at least one pair of complimentary electrode layers and a dielectric elastomer layer, the laminate having a thickness of 200 μm or less.

[12] The dielectric elastomer actuator according to [11], in which
the laminate has a thickness of 100 μm or less.

[13] The dielectric elastomer actuator according to [11] or [12], in which
the rolled body includes a hollow portion, and
the hollow portion has an inner diameter of 10 mm or less.

[14] An apparatus, including
the dielectric elastomer actuator according to any one of [11] to [13].

[15] The apparatus according to [14], in which
the apparatus is an operation input apparatus or a transducer.

[16] An information processing system, including
the apparatus according to [14] or [15].

The embodiments and examples of the present disclosure have been specifically described above. However, the present disclosure is not limited to the embodiments and examples described above, and various modifications based on technical ideas of the present disclosure may be made thereto.

For example, the configurations, the methods, the steps, the shapes/the forms, the materials, the numerical values, and the like in the embodiments and examples described above are merely illustrative, and a configuration, a method, a step, a shape/a form, a material, a numerical value, and the like that are different from those described above may be used as necessary. Further, the configurations, the methods, the steps, the shapes/the forms, the materials, the numerical values, and the like in the embodiments and examples described above may be combined without departing from the spirit of the present disclosure.

Further, as used herein, the numerical-value range shown using “-” indicates a range that includes, as a minimum value and a maximum value, respective numerical values placed before and after “-”. With respect to the gradually varying numerical-value range described herein, an upper limit of a certain numerical-value range may be replaced with an upper limit of another numerical-value range, or a lower limit of the certain numerical-value range may be replaced with a lower limit of the other numerical-value range.

### REFERENCE SIGNS LIST

10 base member layer
11 dielectric elastomer layer
12 electrode layer
13 laminate

1. A method for manufacturing a rolled dielectric elastomer actuator, the manufacturing method comprising:
a rolling step to roll at least one pair of complimentary electrode layers and a dielectric elastomer layer around a core to obtain a rolled body;
a change step to change a state of the core after the rolling step; and
a removal step to remove the core from the rolled body after the change step.

2. The manufacturing method according to claim 1, wherein
the core is a core in a substantially columnar form.

3. The manufacturing method according to claim 1, wherein
the core is a core that is in a substantially columnar form and formed using a material that liquid penetrates successfully.

4. The manufacturing method according to claim 1, wherein
the core is a core that is in a substantially columnar form and that includes a fiber material or a porous material.

5. The manufacturing method according to claim 1, wherein
the core is a hollow core in a substantially columnar form.

6. The manufacturing method according to claim 1, further comprising
a cutting step to cut the rolled body obtained by the rolling around the core, such that a complimentary electrode layer of the at least one pair of complimentary electrode layers is exposed.

7. The manufacturing method according to claim 1, wherein
the rolled body obtained by the rolling step includes an adhesive layer between the core and the rolled body.

8. The manufacturing method according to claim 7, wherein
the adhesive layer contains water-soluble polymers.

9. The manufacturing method according to claim 1, wherein
the change step includes bringing the core into contact with liquid or heating the core.

10. The manufacturing method according to claim 1, wherein
the change step includes bringing the core into contact with liquid, and
the liquid penetrates the core.

11. A dielectric elastomer actuator, comprising
a rolled body of a laminate including at least one pair of complimentary electrode layers and a dielectric elastomer layer, the laminate having a thickness of 200 μm or less.

12. The dielectric elastomer actuator according to claim 11, wherein
the laminate has a thickness of 100 μm or less.

13. The dielectric elastomer actuator according to claim 11, wherein
the rolled body includes a hollow portion, and
the hollow portion has an inner diameter of 10 mm or less.

14. An apparatus, comprising
the dielectric elastomer actuator according to claim 11.

15. The apparatus according to claim 14, wherein
the apparatus is an operation input apparatus or a transducer.

16. An information processing system, comprising
the apparatus according to claim 14.
